(19) United States
(12) Patent Application Publication
(10) Pub. No.: US 2026/0092952 A1
(43) Pub. Date: Apr. 2, 2026

(54) PROBE SYSTEM, PROBE CARD, PROBE HEAD, AND PROBE FOR TESTING ELECTRONIC DEVICE UNDER TEST INTEGRATED ON A SEMICONDUCTOR WAFER, AND ELECTRONIC DEVICE TESTED BY THE PROBE CARD

(71) Applicant: MPI CORPORATION, Zhubei City (TW)

(72) Inventors: Chin-Yi Lin, Zhubei City (TW); Tsung-Yi Chen, Zhubei City (TW); Yi-Zhen Xie, Zhubei City (TW); Yun-Hui Shen, Zhubei City (TW); Che-Wei Lin, Zhubei City (TW)

(21) Appl. No.: 19/272,220

(22) Filed: Jul. 17, 2025

Related U.S. Application Data
(60) Provisional application No. 63/673,331, filed on Jul. 19, 2024.

(51) Int. Cl. G01R 1/073; G01R 31/28

(52) U.S. Cl. CPC G01R 1/07371; G01R 31/2831

(57) ABSTRACT

A probe includes a probe tip configured to contact a corresponding pad on an electronic device under test during testing. The probe further includes a probe tail positioned opposite to the probe tip. Between the probe tip and the probe tail, the probe includes a probe body extending along a longitudinal axis. The probe body includes a slit extending along the longitudinal axis, thereby defining two probe arms separated by the slit. A transverse cross-section of the probe body, taken perpendicular to the longitudinal axis, has a width side and a thickness side, with the two probe arms arranged along the width side. Each of the two probe arms is formed with a bump structure within the slit, wherein the two bump structures face each other across the slit.

### CROSS-REFERENCE TO RELATED APPLICATIONS

This application claims priority to U.S. Provisional Application No. 63/673,331 filed on Jul. 19, 2024, the contents of which are incorporated herein by reference in its entirety.

### BACKGROUND OF THE INVENTION

The present disclosure relates to a probe system, a probe card, a probe head, and a probe structure. More particularly, the present disclosure relates to a probe system, a probe card, a probe head, and a probe structure configured to reduce probe rigidity so as to meet the requirements of high-frequency/high-speed testing and high-current testing.

A probe card is a tool for testing the electrical properties of a semiconductor wafer or a packaged device, and generally comprises at least a probe head, a space transformer, and a circuit board. The probe head may comprise a plurality of probes, each probe being capable of contacting a pad of an electronic device under test (DUT) integrated in the semiconductor wafer to test electrical performance of the electronic device under test. The type of pad corresponds to different types of contact regions on a probe tip. For example, a pad having a bump type corresponds to a blunt-type contact region, while a pad having a flat type corresponds to a sharp-type contact region.

During testing, the probe and the electronic device under test relatively move along a longitudinal axis (i.e., the Z-axis) by a distance, which is the vertical movement of the probe (also referred to as overdrive/overtravel). Typically, the electronic device under test is carried by a chuck and is moved upward from a contact height toward the probe, such that a contact region of the probe tip contacts and presses against the pad of the electronic device under test. This ensures sufficient mechanical contact between the probe tip and the pad and ensures good electrical connection between the probe and the electronic device under test. However, when the contact region of the probe tip presses against the pad of the electronic device under test in the above manner, differences in rigidity among probes affect the magnitude of the force applied by the contact region of each probe to the pad of the electronic device under test under the condition of a fixed displacement amount (i.e., the vertical movement). Specifically, the higher the overall rigidity of the probe, the greater the force applied on the pad under the same displacement amount (vertical movement). The greater the force applied by the contact region of the probe to the pad of the electronic device under test, the greater the potential wear on the pad and/or the probe itself (i.e., the contact region of the probe tip). Accordingly, it is apparent that the rigidity of the probe affects the likelihood of causing excessive or improper wear to the pad of the electronic device under test and/or to the probe itself (i.e., the contact region of the probe tip) during testing.

In recent years, the demand for high-frequency/high-speed testing of electronic devices under test has increased. As the data transmission rate during testing increases (for example, from 50-60 gigabits per second (Gbps) to above 100 Gbps), impedance matching between the overall probe head and the electronic device under test becomes increasingly significant for high-speed signal transmission. When the impedance of a test path (i.e., a signal transmission path) is mismatched, the effect of return loss becomes significant. To meet the demand for high-frequency/high-speed testing, probe designers expect to shorten the probe length to facilitate transmission of high-frequency/high-speed signals. In addition to the demand for high-frequency/high-speed testing, high-current testing has also become an increasingly important testing direction in the technical field of the present disclosure. To meet the demand for high-current testing, probe designers expect to increase the thickness of the probe to facilitate high-current transmission. However, both shortening the probe length and increasing the probe thickness are measures that increase the overall rigidity of the probe. As described above, the stronger the overall rigidity of the probe, the higher the likelihood that excessive or improper wear will be caused to the pad of the electronic device under test during testing, and even damage to other parts of the electronic device under test. As a corresponding solution, in the art there exists an approach of modifying the manufacturing process of a contact probe from forming a solid bar-shaped probe body to forming a multilayer structure having a plurality of probe arms and slits between the probe arms (equivalent to providing the probe body with an opening/hole/slot). This modification can reduce the rigidity of the contact probe, thereby reducing the pressure applied by the probe to the corresponding pad, while ensuring sufficient elasticity of the probe body.

### SUMMARY OF THE INVENTION

In the above prior art, although approaches for reducing the rigidity of contact probes have been provided, such approaches also face the problem that the probe arms may laterally deflect under force during the testing process. More specifically, when a contact probe is elastically compressed under probing pressure (Apply OD) (i.e., when the probe body undergoes buckling), the probe arms may generate varying degrees of lateral deflection. This condition changes the spacing between probe arms, and certain portions of adjacent probe arms may approach each other or even abut against each other (i.e., direct contact occurs). This further brings several technical difficulties. First, for a single contact probe, when the probe operates thousands or even tens of thousands of times, friction causes the contact portion to wear and become thinner, thereby increasing resistance. This may result in excessive current flow and further cause a burning probe problem, which is an adverse factor to the durability of the contact probe. Even when a bump is disposed on one side of a probe arm, the other probe arm without the bump may still suffer wear caused by friction with the bump, leading to the occurrence of the above situation. In addition, for a plurality of contact probes (particularly, for example, differential pairs), when the spacing between two adjacent contact probes increases, impedance matching performance deteriorates, which is an adverse factor to the electrical performance of the contact probe in high-frequency/high-speed testing.

In view of the foregoing, there is a need in the art for a solution that not only reduces the rigidity of a probe but also effectively controls the above adverse factors caused by lateral deflection of the probe arms, thereby enabling contact probes to more effectively meet high-frequency/high-speed testing requirements and/or high-current testing requirements.

To at least address the above technical problems, the present disclosure provides a probe for physically contacting an electronic device under test. The probe may comprise a probe tip configured to contact a corresponding pad of the electronic device under test during testing. The probe may further comprise a probe tail disposed opposite to the probe tip. The probe may further comprise a probe body located between the probe tip and the probe tail and extending along a longitudinal axis. The probe body may comprise a slit extending along the longitudinal axis such that the probe body has two probe arms separated by the slit. A transverse cross-section of the probe body perpendicular to the longitudinal axis may have a width side and a thickness side, and the two probe arms are arranged along the width side. Each of the two probe arms may have a bump structure within the slit, thereby forming two bump structures that face each other within the slit.

To at least address the above technical problems, the present disclosure further provides a probe head for functionally testing an electronic device under test integrated in a semiconductor wafer. The probe head may comprise a probe pair, each probe pair comprising two probes as described above. The probe head may further comprise an upper guide plate unit comprising a first through-hole pair, the probe pair passing through the first through-hole pair. The probe head may further comprise a lower guide plate unit comprising a second through-hole pair, the probe pair passing through the second through-hole pair. The two probes of the probe pair correspond to the same buckling direction, and the buckling direction is parallel to the width side.

To at least address the above technical problems, the present disclosure further provides a probe card for functionally testing an electronic device under test integrated in a semiconductor wafer. The probe card may comprise a circuit board, a space transformer disposed on the circuit board, and the probe head as described above. The probe head may be disposed on a side of the space transformer opposite to the circuit board, wherein the probe tail of each probe of the probe head is configured to be electrically connected to the space transformer.

To at least address the above technical problems, the present disclosure further provides a probe system for functionally testing an electronic device under test integrated in a semiconductor wafer. The probe system may comprise a fixture configured to support the semiconductor wafer. The probe system may further comprise a test equipment configured to be electrically connected to the electronic device under test and to establish an electrical test procedure. The probe system may further comprise the probe card as described above, disposed on the test equipment.

To at least address the above technical problems, the present disclosure further provides an electronic device. The electronic device utilizes the probe card as described above to perform a high-frequency test procedure, wherein the high-frequency test procedure uses a high-frequency signal for testing, and the high-frequency test procedure is a loopback test procedure.

In summary, the probe system and the probe card and probe head included therein provided by the present disclosure reduce the overall rigidity of the probe through the multilayer structure of the probe, such that the force applied by the probe tip on the pad when contacting an electronic device under test during testing is reduced, thereby effectively decreasing the likelihood that the probe causes damage to the electronic device under test due to contact during testing. Accordingly, the present disclosure allows probe designers to increase the thickness of the probe and/or shorten the length of the probe in order to improve electrical performance of the probe, thereby meeting the electrical requirements of high-speed (high-frequency) and/or high-current testing, with enhanced signal integrity.

In addition, by providing two bump structures disposed on two adjacent probe arms and facing each other, the present disclosure effectively confines the contact portions of the probe arms during the process of buckling of the probe body to such positions. Since the portions of the probe arms having the bump structures substantially increase in width, wear caused by frictional contact between probe arms can be reduced, thereby avoiding a shortened service life. During a testing operation performed by the probe of the present disclosure, when the contact tip of the probe contacts a corresponding pad on a device under test, the deflection direction of the probe arms can be controlled to remain more consistent, and different probe arms of the probe body can maintain a certain spacing even when deflecting under overdrive (OD) compression, particularly at the portions where the bump structures are provided. Compared with probes in the prior art that do not have bump structures, the probe of the present disclosure enables the spacing between probe bodies of adjacent probes in the same probe pair to remain smaller (that is, the degree of reduction in spacing between probe arms within each probe during testing is lowered, and the extent of expansion of spacing between two probes is further reduced). If the probe bodies of adjacent probes in a probe pair can maintain a sufficiently close spacing, this also contributes to improved electrical performance in high-speed/high-frequency testing.

The above content is not intended to limit the present disclosure, but only briefly describes the technical problems that can be solved by the present disclosure, the technical means that can be adopted, and the technical effects that can be achieved, so that a person having ordinary skill in the art can have a preliminary understanding of the present disclosure. The embodiments of the present disclosure will be described below in conjunction with the drawings.

### BRIEF DESCRIPTION OF DRAWINGS

As shown below:

FIG. 1 illustrates a wafer testing system including a probe card, a probe head, and probes according to one or more embodiments of the present disclosure.

FIG. 2A illustrates a side view structure of a probe according to one or more embodiments of the present disclosure.

FIG. 2B illustrates a transverse cross-sectional view of a probe body of the probe shown in FIG. 2A.

FIG. 2C illustrates a partial structure of the probe shown in FIG. 2A.

FIG. 3A illustrates an enlarged partial view of probe bodies of two probes during a testing process according to one or more embodiments of the present disclosure.

FIG. 3B illustrates a further enlarged view of the bump structures shown in FIG. 3A.

FIGS. 4A and 4B illustrate various side view structures of a probe according to one or more embodiments of the present disclosure.

FIG. 5 illustrates various transverse cross-sectional views of probe bodies of a probe according to one or more embodiments of the present disclosure.

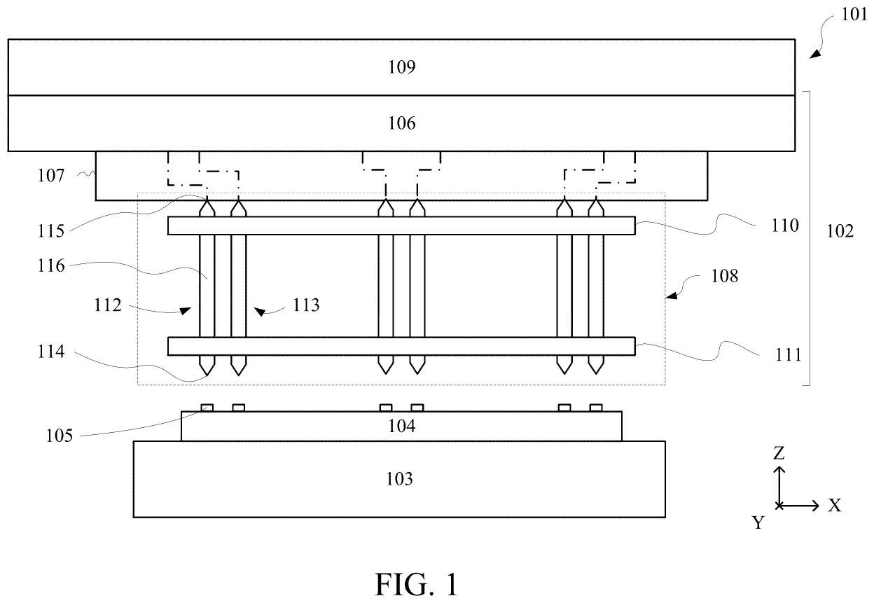

The contents shown in FIGS. 1 to 5 are merely examples for illustrating embodiments of the present disclosure and are not intended to limit the scope of the present disclosure.

### DETAILED DESCRIPTION OF THE INVENTION

In the following description, the present disclosure will be described below through multiple embodiments, but these embodiments are not intended to limit the present disclosure to any specific environment, applications, structures, processes or situations. The attached drawings are proposed to assist in the description of the embodiments, but limit the protection scope of the present disclosure. In the attached drawings, elements which are not directly related to this invention are omitted from depiction. Dimensions and dimensional relationships among individual elements in the attached drawings are only exemplary examples and are not intended to limit this invention. Unless stated particularly, same (or similar) element numerals may correspond to same (or similar) elements in the following description without inconsistency with this invention. If it can be implemented, the number of each element described below may be one or more unless otherwise specified.

The terminology used herein is for the purpose of describing the embodiments only and is not intended to limit the present disclosure. The singular forms “a” and “an” are intended to include the plural forms as well, unless the context clearly indicates otherwise. The terms “comprises,” “comprising,” “includes,” “including,” etc., specify the presence of the stated features, integers, operations, elements, and/or components, but do not preclude the presence or addition of one or more other features, integers, operations, elements, components, and/or groups thereof. The term “and/or” includes any and all combinations of one or more of the associated listed items. Although the terms “first”, “second” and “third” etc., may be used herein to describe various elements, these elements should not be limited by these terms. These terms are merely used to distinguish one element from another element. Thus, for example, a “first” element could also be termed a “second” element, and vice versa, without departing from the spirit and scope of this invention.

Referring to FIG. 1, a probe system 101 according to one or more embodiments of the present disclosure is illustrated. The probe system 101 may comprise at least a probe card 102 and a chuck 103. The probe card 102 may be used for electrically connecting to and/or mechanically contacting an electronic device under test 104, and for testing electrical performance of the electronic device under test 104. The probe card 102 may be configured to test the electronic device under test 104. The electronic device under test 104 may be a semiconductor wafer. The chuck 103 may be used for carrying the electronic device under test 104 for detection by the probe card 102. The electronic device under test 104 may comprise one or more pads (e.g., a pad 105 shown in FIG. 1), such that contact regions of the probes are configured to contact one of the one or more pads of the electronic device under test 104 during testing (in FIG. 1, the contact regions of the probes are shown as not yet contacting the corresponding pads).

The probe card 102 may comprise a circuit board 106, a space transformer 107, and a probe head 108. The space transformer 107 may be disposed on the circuit board 106, and the probe head 108 may be disposed on the space transformer 107. The probe head 108 may generally comprise a plurality of probes and at least one guide plate, wherein one end of each probe may be electrically connected to the circuit board 106 through the space transformer 107, and the other end may contact a pad (e.g., a metal solder pad or a conductor bump) on the electronic device under test 104 during testing. It should be noted that the description above regarding the space transformer 107 being disposed on the circuit board 106 is merely based on conventional relative size relationships of the space transformer 107 and the circuit board 106, and does not limit the space transformer 107 to being necessarily physically located above the circuit board 106.

The test equipment 109 may perform various test procedures and/or communicate test information to the electronic device under test through the probe card 102. The test equipment 109 may be, for example, a test head of a tester. In certain testing methods, a loopback test procedure may be included, in which the electronic device under test 104 itself generates a required high-frequency test signal, the signal passes through the probe card 102, and is then transmitted back to the electronic device under test 104 for detection, so as to determine whether the electronic device under test 104 operates normally.

The circuit board 106 may comprise a wafer side and a tester side. The wafer side and the tester side of the circuit board 106 are oppositely disposed, and the tester side of the circuit board 106 is provided for connection to the test equipment. In the present embodiment, when the probe card 102 is used in the test equipment 109, the wafer side may be a lower surface of the circuit board 106, facing the space transformer 107 and/or facing the electronic device under test 104, while the tester side may be an upper surface of the circuit board 106, facing away from the electronic device under test 104 and/or facing the test equipment 109. In the present embodiment, the circuit board 106 is an ordinary printed circuit board, which has a top surface, a bottom surface, and multiple signal lines inside, and contact pads electrically connected to the signal lines are formed on the top surface and the bottom surface. The contact pads on the top surface of the circuit board 106 may be contacted by pogo pins of the test equipment. Test signals of the test equipment may be transmitted through the signal lines to the bottom surface of the circuit board 106.

The space transformer 107 may also comprise a wafer side and a tester side. It should be noted that the space transformer 107 may be formed of a multilayer circuit board. The tester side of the space transformer 107 may be connected to the wafer side of the circuit board 106. In the present embodiment, when the probe card 102 is used in the test equipment 109, the wafer side of the space transformer 107 may be a lower surface of the space transformer 107, facing the probe head 108 and/or the electronic device under test 104, while the tester side of the space transformer 107 may be an upper surface thereof, facing away from the electronic device under test 104, facing the circuit board 106, and/or facing the test equipment 109. In the present embodiment, the space transformer 107 may include a multilayer organic (MLO) substrate or a multilayer ceramic (MLC) substrate, which may be adjusted in material according to actual requirements, and the present disclosure is not limited thereto. In the present embodiment, the space transformer 107 comprises internal signal lines, with contact pads formed on its top surface and bottom surface and electrically connected to the internal signal lines, wherein the spacing between the contact pads on the top surface is greater than the spacing between the contact pads on the bottom surface. The space transformer 107 is mechanically and electrically connected to the wafer side of the circuit board 106, namely, the bottom surface of the circuit board 106, and is disposed beneath the circuit board 106, such that the contact pads on the top surface of the space transformer 107 may be electrically connected to the contact pads on the bottom surface of the circuit board 106, thereby electrically connecting the internal signal lines of the space transformer 107 to the signal lines of the circuit board 106. It should be noted that the space transformer 107 and the circuit board may also be indirectly mechanically and/or electrically connected through another substrate (e.g., a spacer board), such that the space transformer 107 is indirectly disposed on the wafer side of the circuit board 106.

The probe head 108 may be disposed on the wafer side of the space transformer 107 in a mechanically and/or electrically connected manner. As shown in FIG. 1, the probe head 108 may comprise an upper guide plate unit 110, a lower guide plate unit 111, and a plurality of probes (e.g., probes 112 and 113 shown in FIG. 1). Each probe may physically contact the electronic device under test 104. The upper guide plate unit 110 may comprise at least one upper guide plate, each of which may be provided with a plurality of upper guide holes. The lower guide plate unit 111 may comprise at least one lower guide plate, each of which may be provided with a plurality of lower guide holes. The upper guide plate unit 110 and the lower guide plate unit 111 may be oppositely disposed along a longitudinal axis (e.g., substantially along the Z-axis of a local coordinate system of FIG. 1, hereinafter referred to as the “Z-axis”). Each probe may pass through a corresponding one of the plurality of upper guide holes and a corresponding one of the plurality of lower guide holes.

The probes are typically made of special metals having good electrical and mechanical properties. By pressing the probe head 108 against the electronic device under test 104, good connection between the probes and the pads of the electronic device under test 104 can be ensured. During pressurized contact, the probes may slide within the corresponding guide holes of the upper and lower guide plate units, and the probes may bend within an air gap between the upper and lower guide plate units.

According to certain embodiments of the present disclosure, each probe included in the probe head 108 may be a probe referred to in the art as a “buckling beam” probe, that is, the probe body may have a constant transverse cross-section (e.g., substantially rectangular, preferably square or rectangular) over its entire length, wherein the probe body is adapted to bend and/or stretch substantially at a central position thereof, thereby deforming during testing of the electronic device under test 104. However, in certain other embodiments, each probe does not necessarily have a constant transverse cross-section over its entire length.

As used herein, the term “substantially rectangular” refers to a rectangle and other actual results that may arise when manufacturing a probe body with a rectangular transverse cross-section, such as a trapezoid. More specifically, those of ordinary skill in the art should understand that even if the equipment for manufacturing probes is designated to fabricate probes having rectangular transverse cross-sections, the actual fabricated probes may still have certain tolerances or manufacturing errors, such that the shape of the probe body transverse cross-section may not be a geometrically perfect rectangle in some embodiments.

The probes applicable to the present disclosure may at least include straight probes, such as forming wire (FW) probes or micro-electro-mechanical system (MEMS) wire (MW) probes.

As shown in FIG. 1, each probe may comprise a probe tip (e.g., a probe tip 114 included in the probe 112), a probe tail (e.g., a probe tail 115 included in the probe 112), and a probe body (e.g., a probe body 116 included in the probe 112) located between the probe tip and the probe tail. The probe tip may terminate at a contact region and may be configured to be adjacent to a corresponding pad of the electronic device under test 104 integrated in a semiconductor wafer (e.g., the probe tip 114 shown in FIG. 1 is configured to be adjacent to the pad 105 of the electronic device under test 104). The probe tail of each probe may pass through a guide hole in the upper guide plate unit 110 to be electrically connected to the space transformer 107. The probe tail may terminate at a contact end and may be configured to be adjacent to a contact pad of the space transformer 107 (not shown in the figure). The probe body may extend substantially along the longitudinal axis between the probe tip and the probe tail. The probe tip of each probe may be used for electrically contacting the electronic device under test 104. The probe tip of each probe may be configured to communicate electrically and/or communicatively contact with a corresponding pad of the electronic device under test 104. The term “communicate” refers to that the probe may be configured to transmit test signals of the probe card 102 to the electronic device under test 104, and/or to be configured to receive signals from the electronic device under test 104.

Many embodiments of the present disclosure primarily relate to various implementations of the probe structure, and extend to a probe head, a probe card, and a probe system including the probe structure. It should be noted that although the probe structures in different embodiments of the present disclosure may vary slightly, the plurality of probes included in the probe head of each embodiment may generally comprise at least one probe pair (e.g., the probe pair composed of probe 112 and probe 113 shown in FIG. 1). In some embodiments, each probe pair may be used to transmit a set of differential signals, and such a probe pair may also be referred to as a “differential pair.” In preferred embodiments of the present disclosure, the differential pair may use two single-ended signal lines (e.g., P line and N line) respectively connected to TX+ and RX+, and TX- and RX-, to simultaneously transmit signals, wherein the two signals have the same voltage amplitude but opposite phases.

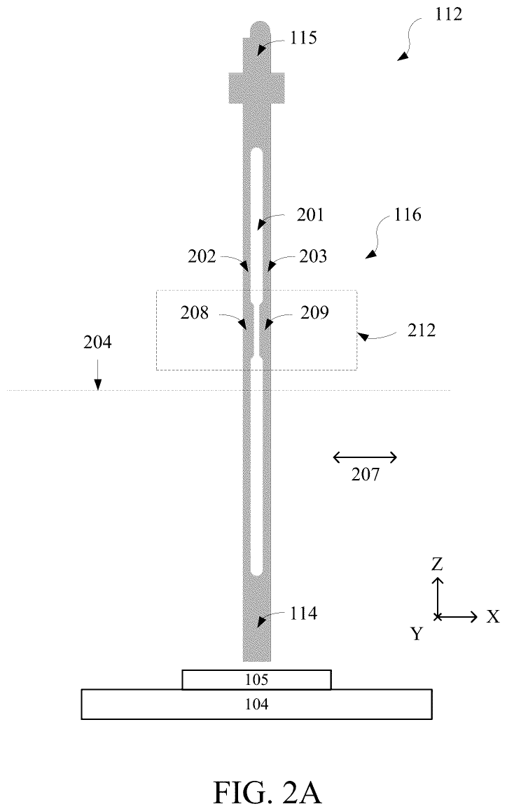

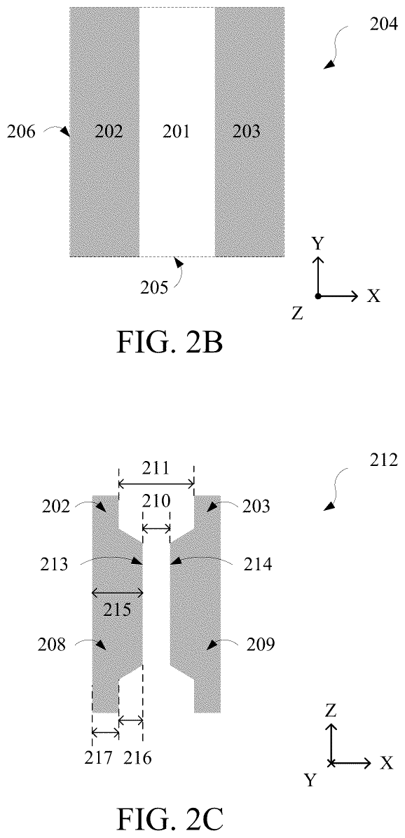

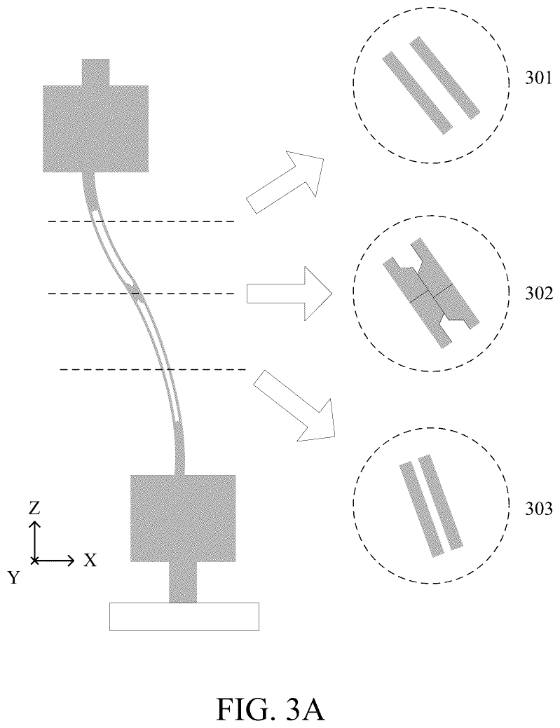

FIG. 2A takes the probe 112 as an example to illustrate an exemplary structure that each probe in the probe head 108 may have. Those of ordinary skill in the art can understand the possible structures of the probes in the probe head 108 based on the description of the probe 112. Referring first to FIG. 2A, which illustrates a side view structure of the probe 112 from a perspective similar to that of FIG. 1, the probe body 116 of the probe 112 extends along a longitudinal axis (Z-axis) and may comprise a slit 201. The slit 201 extends along the longitudinal axis and causes the probe body 116 to have two probe arms separated by the slit 201, namely a probe arm 202 and a probe arm 203.

The probe body 116 has a transverse cross-section 204 perpendicular to the longitudinal axis (Z-axis). Referring also to FIG. 2A and FIG. 2B, the transverse cross-section 204 has a width side 205 and a thickness side 206. The probe arms 202 and 203 are arranged along the width side 205. The slit 201 is located between the probe arms 202 and 203. In some embodiments, the probe arms 202 and 203 may be symmetrical with respect to the slit 201.

The width side 205 may be parallel to a bending direction 207 of the probe arms 202 and 203 when the probe 112 contacts the electronic device under test 104. In some embodiments, the bending direction 207 may be parallel to the width side 205, as jointly illustrated in FIG. 2A and FIG. 2B. Furthermore, FIG. 2A shows the bending direction 207 as being parallel to the X-axis direction, while FIG. 2B further shows the width side 205 as also being parallel to the X-axis direction. Therefore, during testing, the probe arms 202 and 203 may bend together toward the right side or left side in FIG. 2A, namely in the positive direction or negative direction of the X-axis.

In some embodiments, a thickness of the probe body 116 may be greater than or equal to a width of the probe body 116. The width may be represented by the width side 205, and the thickness may be represented by the thickness side 206. For a multilayer-structured probe in which the probe body thickness is greater than or equal to the width, the effect of reducing probe body rigidity is significantly superior to that of a multilayer-structured probe in which the width is greater than the thickness. Moreover, when the buckling direction of the probe is along the width side direction (e.g., as shown in FIG. 2A), the reduction effect is even more significant.

Referring also to FIG. 2A and FIG. 2C, the probe arms 202 and 203 may respectively comprise bump structures, namely a bump structure 208 and a bump structure 209, located within the slit 201. When the probe body 116 is not buckled (i.e., not deformed under force), the two bump structures may be positioned opposite each other within the slit 201. The bump structures are contact points where the two probe arms support each other during the testing process, thereby improving stability when the probe body buckles and ensuring consistency of the bending direction. The bump structure 208 and the bump structure 209 are respectively formed by portions of the probe arms 202 and 203 protruding from opposite inner sidewalls toward a central axis of the slit 201, and are arranged opposite each other.

In some embodiments, the two bump structures may be separated in the direction of the width side 205, for example, in the positive/negative direction of the X-axis shown in FIG. 2A. A spacing 210 between the bump structure 208 and the bump structure 209 in the direction of the width side 205 may be smaller than a spacing 211 between the probe arm 202 and the probe arm 203 in the same direction.

In some embodiments, when viewed from the positive Y-axis direction in FIG. 2A (i.e., the perspective shown in FIG. 2A), the bump structures of each probe (e.g., the bump structure 208 and the bump structure 209) may be substantially trapezoidal. In some embodiments, a cross-section of the bump structures of each probe (e.g., the bump structure 208 and the bump structure 209) taken along a plane parallel to the long side and width side of the probe body (in other words, perpendicular to the X-Z plane in FIG. 2A) may also be substantially trapezoidal. It should be understood that when the term “substantially” is used to modify a degree or relationship, its scope is not limited to the specific degree or relationship itself, but also encompasses the entire range of variations. For example, the term “substantially” may cover at least up to 95%. As used herein, the term “substantially trapezoidal” with respect to the bump structures refers to that, when viewed from the direction of the thickness side of the probe body (i.e., the Y-axis direction), the side profile of the bump structures may not necessarily be a geometrically perfectly symmetric or ideal trapezoid. However, if the overall shape has a pair of non-parallel slanted sides and a pair of approximately parallel sides, and exhibits a general trend of being wider on one side and narrower on the other, it may be considered “substantially trapezoidal.” For example, if the deviation of the extension angle of its two sides relative to an ideal trapezoid does not exceed ±10 degrees, and such geometric deviation does not affect the realization of functions such as positioning, guiding, or alignment during processing, it still falls within the meaning of “substantially trapezoidal” as claimed in the present disclosure.

FIG. 2C illustrates a region 212 of the probe body 116 in FIG. 2A, corresponding to positions of the bump structure 208 and the bump structure 209. The bump structure 208 and the bump structure 209 may respectively have a contact surface 213 and a contact surface 214. When the probe body 116 undergoes elastic deformation (i.e., buckling) due to axial compression during testing, the bump structure 208 and the bump structure 209 may contact each other through their respective contact surfaces during deformation and undergo restricted relative sliding. In other words, while the probe arms are in contact, they still retain a degree of freedom to slide. Through this sliding behavior, localized stress concentration caused by contact may be dispersed, and part of the elastic strain energy may also be absorbed. The term “restricted relative sliding” as used herein refers to that although the two bump structures (such as the bump structure 208 and the bump structure 209) may undergo relative displacement along a specific direction after contact, the range of sliding is limited by structural geometry, material elasticity, or the design of external guiding components, such that excessive movement of the probe arms or loss of positioning functionality does not occur. The sliding may be adjusted in terms of distance and direction by the size of the bumps, tolerance control, or cooperating surface designs (such as stop surfaces, limiting slopes, or friction coefficient regulation). Through this mechanism, the probe may release localized energy when subjected to axial force, thereby reducing the risk of probe arm damage while maintaining overall guidance and recoverability of the structure.

In addition, sliding helps to reduce wear and deformation between the probe arms caused by contact, and maintains a stable spatial relationship between the probe arms (e.g., the spacing between the two probe arms within the same probe), which is beneficial for impedance control of high-frequency signals (such as differential signals). Compared with probes in the prior art without bump structures or having only a single-side bump structure, maintaining the spatial relationship between probe arms also allows the spacing between probe bodies of adjacent probes in the same probe pair to remain smaller (i.e., the degree of reduction of probe arm spacing within each probe due to arms approaching each other during testing is lowered, and consequently the extent of expansion of the spacing between two probes is also reduced). If the probe bodies of adjacent probes in a probe pair can maintain sufficiently close spacing, this also contributes to improved electrical performance in high-speed/high-frequency testing.

In some embodiments, each bump structure may have a width 216 in the width side direction (i.e., the height of the trapezoid), and each probe arm, at a portion corresponding to the bump structure (e.g., within the region 212 shown in FIG. 2C), may have a width 217 in the width side direction (X-axis direction). The width 216 of the bump structure may be not greater than the width 217 of the probe arm. In other words, the sum of the widths of each probe arm and its corresponding bump structure (e.g., the width 215 shown in FIG. 2C) may be greater than 1 time and not greater than 2 times the width of the same probe arm structure (e.g., the width 217 shown in FIG. 2C). That is, the maximum width of the bump structure may be equal to the probe arm width at the same location, so as to be suitable for abutting against the opposite bump structure.

In some embodiments, the material of the bump structure may be the same as that of the probe body. In this case, the bump structure may be integrally formed during the process of slotting the probe body to create the slit. However, in certain other embodiments, the bump structure may have a material different from that of the probe body, and may be, for example but not limited to, a metal alloy, engineering plastic, polymer elastomer, or ceramic material. In such cases, the bump structure may be attached to the probe body by, for example, welding, adhesive bonding, structural embedding, laser fusing, or micromechanical bonding, so as to ensure stability and functionality under loading conditions. The selection of different materials is helpful for optimizing sliding friction characteristics, stress distribution, wear resistance, or energy absorption capability, thereby further improving the performance and service life of the overall structure.

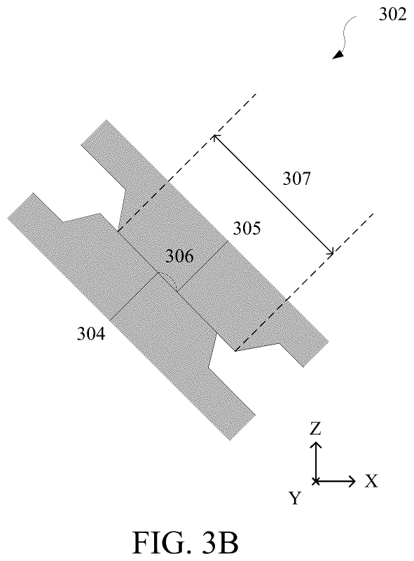

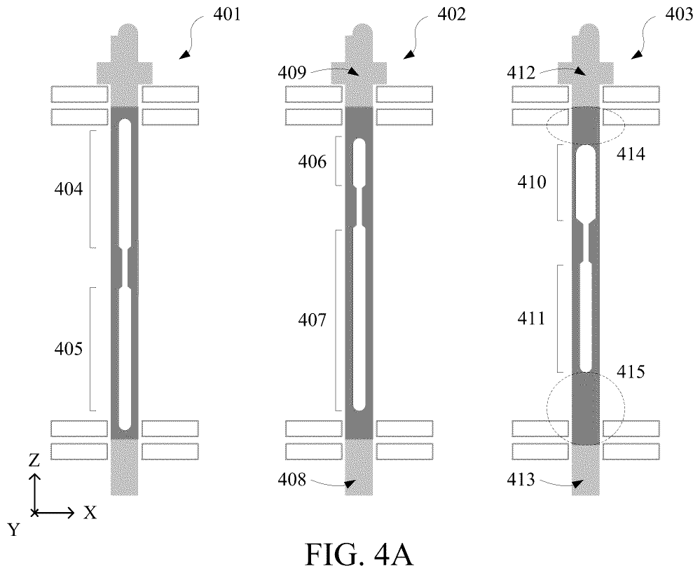

Referring to FIG. 3A, two probes in a probe pair are illustrated in a buckled condition during testing, with their bump structures contacting each other and sliding relative to each other. The region 302 shown in FIG. 3A presents the two bump structures contacting each other through their respective contact surfaces and undergoing restricted relative sliding. Regions 301 and 303 respectively illustrate conditions above and below the bump structures. Although the contact of the two bump structures in the region 302 can effectively maintain a basic spacing between the probe arms and thereby avoid contact between the probe arms at these locations under most implementation conditions, it should be understood that under extreme bending or excessive compression conditions, local contact between the probe arms in the above regions may still occur.

In some embodiments, two ends of each probe in a probe pair may be offset by a distance by the upper guide plate unit and the lower guide plate unit in a direction parallel to the width side of the probe body transverse cross-section (e.g., the X-axis direction in FIG. 3A), as shown in FIG. 3A. In some embodiments, each probe may further be offset by another distance, smaller than the foregoing distance, by the upper guide plate unit and the lower guide plate unit in a direction parallel to the thickness side of the probe body transverse cross-section (e.g., the Y-axis direction in FIG. 3A).

Referring next to FIG. 3B, a further enlarged view of the region 302 shown in FIG. 3A is illustrated. When the two bump structures contact each other and slide relative to each other, the amount of sliding may be represented by a spacing 306 between respective centerlines 304 and 305 of the two bump structures.

In some embodiments, a length of each contact surface of the bump structures may be not less than the amount of movement of relative sliding between the two bump structures. Taking the contents shown in FIG. 3B as an example, in a case where the two bump structures are structurally identical, a contact surface length 307 of the two bump structures may be not less than the amount of movement of relative sliding between the two bump structures, namely the spacing 306 described above. In some embodiments, the length of each contact surface of the bump structures may be not less than 10 micrometers.

The present disclosure, by providing bump structures capable of sliding relative to each other, enables the probe to have the capability of controlled deflection and buffered contact during compression and buckling operation. Compared with conventional fixed bump designs that provide only limiting action and lack sliding capability (i.e., a bump disposed on only one probe arm), the relative sliding behavior of the bumps in the present disclosure facilitates guiding and stabilizing the consistency of the probe arm deflection direction, thereby allowing a multi-probe array to maintain an orderly arrangement and uniform spacing during compression, which is particularly critical for impedance matching and stability of high-frequency signal transmission. In addition, the relative sliding mechanism can also effectively disperse localized stress concentration caused by contact, reduce the risk of wear and permanent deformation of the probe arm structure, and improve durability and reliability of the probe as a whole.

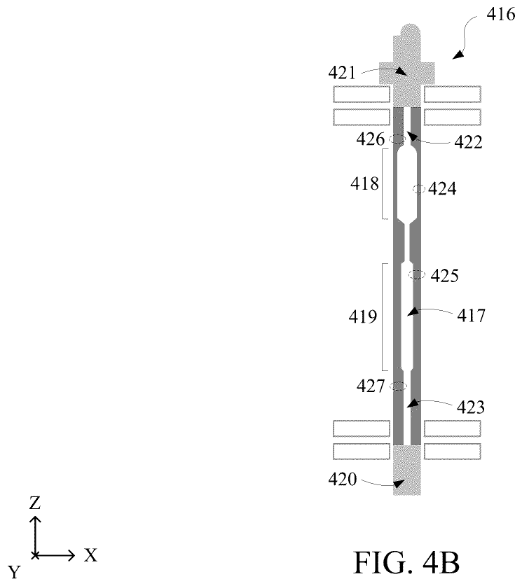

Referring to FIG. 4A, the illustrated content may be divided into left, middle, and right portions. Each portion shows, through a probe (i.e., probes 401, 402, 403) together with schematic upper and lower guide plate units, the arrangement of bump structures and slits in the probe body according to one or more embodiments of the present disclosure. As previously described, in a probe having a slit and bump structures in the probe body, the presence of the slit divides the probe body into a plurality of probe arms. For ease of description, FIG. 4A illustrates the case of one slit and two probe arms. The presence of bump structures further divides the probe arms and the slit into upper and lower regions. Depending on the positional arrangement of the bump structures, the lengths of the two regions may be the same or different.

In the embodiment corresponding to the probe 401, the two bump structures divide the slit of the probe body and the probe arms on both sides into an upper region 404 and a lower region 405 of equal length, that is, the positions of the bump structures are level with a middle position of the slit in the direction of the longitudinal axis (Z). Such an arrangement is advantageous in making the resistance distribution of current flowing through the probe body more uniform.

In the embodiment corresponding to the probe 402, the two bump structures divide the slit of the probe body and the probe arms on both sides into an upper region 406 and a lower region 407, and the positions of the bump structures are, in the direction of the longitudinal axis (Z), closer to the probe tail 409 than to the probe tip 408. Therefore, the divided region 406 is relatively near the probe tail 409 and away from the probe tip 408, while the region 407 is relatively near the probe tip 408 and away from the probe tail 409. In other words, a length of the region 406 in the direction of the longitudinal axis (Z) is less than a length of the region 407 in the direction of the longitudinal axis (Z).

In the embodiment corresponding to the probe 403, the two bump structures are similar to those of the probe 402, dividing the slit of the probe body and the probe arms on both sides into an upper region 410 and a lower region 411, with the positions of the bump structures being, in the direction of the longitudinal axis (Z), closer to the probe tail 412 than to the probe tip 413. The difference between the probe 403 and the probe 402 lies in that the probe arms in the upper and lower regions of the probe 402 have the same width, whereas the probe arms in the upper and lower regions (i.e., regions 410 and 411) of the probe 403 have different widths. More specifically, in the embodiments corresponding to the probes 401 and 402, the probe arms of the upper and lower regions are of equal width, while in the embodiment corresponding to the probe 403, the probe arm at the region 410 has a smaller width than that at the region 411. In other words, the upper portion of the probe arm near the probe tail is thinner, and the lower portion near the probe tip is thicker. The variation in the probe arm width (thickness) is related to the bending or mechanical response behavior of the probe during use.

It should be noted that although in the contents shown in FIG. 2A and FIG. 4A, the widths of the two probe arms divided by the slit are the same, in some embodiments, the widths of the two probe arms divided by the slit may be different (i.e., the left and right probe arms in the figure may be of unequal widths).

In addition to the difference in probe arm width (thickness) between the upper and lower regions, the position of the slot (i.e., the positions of the upper and lower ends of the slit) and the lengths of reinforced sections of the probe body may also affect the structural strength or elasticity of the probe during testing. More specifically, taking the probe 403 as an example, the upper reinforced section 414 of the probe body is the section between the upper end of the slit and the probe tail 412, while the lower reinforced section 415 of the probe body is the section between the lower end of the slit and the probe tip 413. In the embodiment corresponding to the probe 403, the length of the lower reinforced section 415 of the probe body may be greater than the length of the upper reinforced section 414 of the probe body. In other words, the distance between the lower end of the slit and the probe tip 413 (i.e., the length of the lower reinforced section 415) may be greater than the distance between the upper end of the slit and the probe tail 412 (i.e., the length of the upper reinforced section 414). The design purpose of the reinforced sections is to control the deflection of the probe body (particularly during downward overdrive), so that the deflection direction becomes more stable.

Referring to FIG. 4B, a probe 416 is illustrated. The probe 416 may have two bump structures, similar to the probe 403 shown in FIG. 4A, and the two bump structures may divide the slit 417 of the probe body and the probe arms on both sides into an upper region 418 and a lower region 419, with the positions of the two bump structures being, in the direction of the longitudinal axis (Z), closer to the probe tail 421 than to the probe tip 420. In addition, the probe 416 may, like the probe 403, have probe arms of different widths in the upper and lower regions (i.e., the regions 418 and 419).

The probe 416 corresponds to a modification of the probe 403 shown in FIG. 4A, in which additional slots are formed at the original upper reinforced section 414 and lower reinforced section 415 of the probe 403 (i.e., forming another slit at each reinforced section). Therefore, the difference between the probe 416 and the probe 403 is that, in addition to the existing slit 417, the probe 416 further comprises a slit 422 formed at the upper reinforced section and a slit 423 formed at the lower reinforced section.

In some embodiments, the slit 422 and the slit 423 may, as shown in FIG. 4B, be connected to and communicate with the slit 417. However, in some embodiments, the slit 422 and/or the slit 423 may not be connected to the slit 417. Since the probe arms may have different widths at the region 418 and the region 419, when the slit 417, the slit 422, and the slit 423 are all connected and communicate, the probe arms may have at least three stages of width variation. As illustrated schematically by the dashed ellipse in FIG. 4B, the probe arms may have four widths, namely a width 424 corresponding to the region 418, a width 425 corresponding to the region 419, a width 426 corresponding to the upper reinforced section, and a width 427 corresponding to the lower reinforced section.

In an embodiment in which the slit 417, the slit 422, and the slit 423 are all connected and communicate, and the slit 422 and the slit 423 have the same width, the probe arms, when viewed from the perspective shown in FIG. 4B, may have three stages of width variation, preferably such that: the width 427 is equal to the width 426 and greater than the width 425, and the width 425 is greater than the width 424.

On the other hand, in an embodiment in which the slit 417, the slit 422, and the slit 423 are all connected and communicate, and the slit 422 and the slit 423 have different widths, the probe arms may have four stages of width variation, preferably such that: the width 427 is greater than the width 426, the width 426 is greater than the width 425, and the width 425 is greater than the width 424.

The widths of the slit 422 and the slit 423 may be smaller than the widths of the slit 417 at the regions 418 and 419, such that even though additional slots are formed at the upper and lower reinforced sections, the overall structural strength thereof is still stronger than that of other regions of the probe body that do not belong to the reinforced sections.

The widths of the slit 422 and the slit 423 may be not less than the width of the slit 417 at the positions of the two bump structures. Relatively, the widths of the two probe arms of the probe 416 at the positions of the slit 422 and the slit 423 may be not greater than the sum of the widths of the bump structures and the widths of the probe arms at the positions of the bump structures.

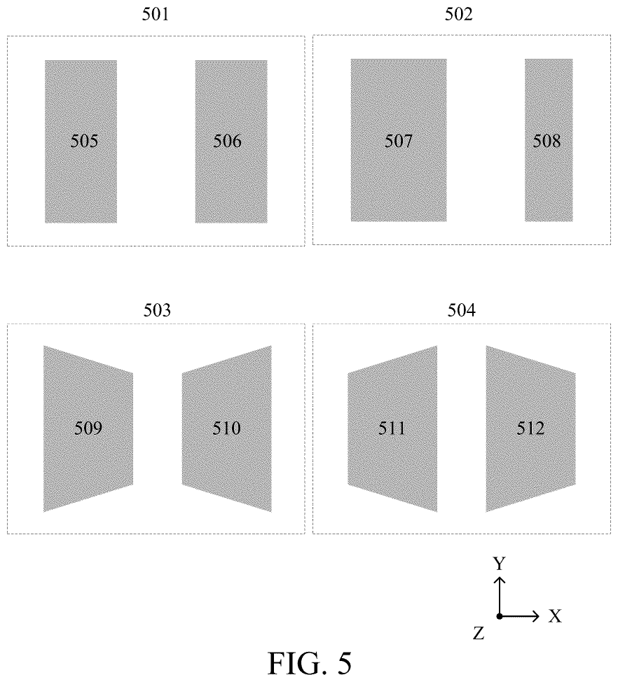

Referring to FIG. 5, multiple transverse cross-sections of probe arms and slits according to several embodiments of the present disclosure are illustrated. In FIG. 5, transverse cross-sections 501, 502, 503, and 504 are shown, which are taken from the probe body in different probe embodiments in the same manner as the transverse cross-section 204 in FIG. 2B. The transverse cross-section 501 comprises two probe arms, namely probe arm 505 and probe arm 506. The transverse cross-section 502 comprises two probe arms, namely probe arm 507 and probe arm 508. The transverse cross-section 503 comprises two probe arms, namely probe arm 509 and probe arm 510. The transverse cross-section 504 comprises two probe arms, namely probe arm 511 and probe arm 512.

In some embodiments, the transverse cross-sections of the two probe arms may be substantially rectangular, as shown in the transverse cross-sections 501 and 502. In some embodiments, the transverse cross-sections of the two probe arms may be substantially trapezoidal, as shown in the transverse cross-sections 503 and 504.

The transverse cross-sections of the two probe arms shown in FIG. 5 are obtained by cutting the probe arms along the X-Y plane perpendicular to the longitudinal axis (Z-axis), at the same or different heights (e.g., the transverse cross-section 204 shown in FIG. 2A). As shown in the four transverse cross-sections 501, 502, 503, and 504, the shapes of the transverse cross-sections of the probe arms in different embodiments may vary slightly at the same or different longitudinal positions, and overall may be categorized as “substantially rectangular” or “substantially trapezoidal.”

As used herein, the term “substantially rectangular” refers to that although the cross-sectional profile may not be a geometrically perfectly symmetric rectangle, its four sides are approximately straight, its opposite sides are approximately parallel, and its angles are close to right angles (e.g., 90±5 degrees). Even if the edges have minor fillets, chamfers, or manufacturing tolerances, such variations do not affect the rectangular functionality and guiding effect of the structure. For example, as shown in the probe arms 505, 506, 507, and 508 in FIG. 5, the transverse cross-sectional shapes of these probe arms provide stable guiding characteristics suitable for cooperating with guide plates or limiting structures to suppress rotation and lateral deviation.

The term “substantially trapezoidal” refers to that the cross-sectional profile has one pair of approximately parallel sides and another pair of non-parallel sides, presenting an overall appearance with one end wider and the other end narrower. For example, the probe arms 509, 510, 511, and 512 shown in FIG. 5 fall into this category. If the deviation of the slanted sides from an ideal trapezoid does not exceed ±10 degrees and such deviation does not impair guiding, alignment, or contact functionality, the shape may be regarded as conforming to the “substantially trapezoidal” form as claimed in the present disclosure.

As used herein, the term “guidability” refers to that the probe or probe arm, through its geometric structural design, can be guided and restricted to move in a specific direction during testing or assembly positioning, thereby preventing twisting, tilting, or lateral deviation, and enhancing overall probe alignment accuracy and test reliability.

In some embodiments, the two probe arms of a probe may have transverse cross-sectional profiles of the same shape but different widths in a direction parallel to the width side (i.e., the X-axis direction). In other words, the thickness of the probe arms may be configured asymmetrically. Such an asymmetric design may be adjusted according to actual stress distribution, guiding requirements, or spatial constraints to optimize structural strength, deformation behavior, or signal transmission stability.

It should be understood that although the drawings illustrate only the case where a pair of bump structures is provided within one slit, this is merely a schematic representation for ease of explanation and does not constitute an absolute limitation on the number of slits or bump structures. In other words, in some embodiments, multiple pairs of bump structures may also be provided within one slit. These bump structures may be distributed along the longitudinal axis (Z-axis) on the two probe arms divided by the slit, either at equal intervals or unequal intervals. Such an arrangement can further enhance the guiding stability and structural support effect between the probe arms, and the sliding characteristics and contact response may be adjusted according to actual requirements.

It should also be understood that although the drawings illustrate only the case where a probe has one slit and two probe arms, this is merely a schematic representation for ease of explanation and does not constitute an absolute limitation on the number of slits or probe arms in the present disclosure. In other words, in some embodiments, multiple slits may be formed in the probe body of a probe. Since the probe arms are formed by division through slits, a probe may have more than two probe arms through a multiple-slit configuration. As for the arrangement of bumps between adjacent probe arms in the same slit, reference may be made to the relevant descriptions of the drawings disclosed herein, and the same design principles and functions may be analogously applied to multi-slit, multi-arm structural configurations.

As used herein, the term “direction of a specific side” (e.g., thickness side, width side, etc.) or “direction of a specific axis” (e.g., X-axis, Y-axis, Z-axis, longitudinal axis, etc.) refers to a direction substantially parallel to the specific side or axis. That is, unless otherwise explicitly specified, descriptions mentioning “direction of a specific side” or “direction of a specific axis” should be understood as directions substantially parallel to the side or axis.

In summary, the multilayer-structured probe provided by the present disclosure, with adjacent probe arms each provided with bump structures, implements a contact control mechanism with sliding capability during compression or buckling operation of the probe. This mechanism not only enhances guiding stability and alignment consistency between probe arms, but also effectively disperses contact stress, suppresses wear and deformation, and maintains impedance stability required for high-frequency signal transmission. Overall, the design of the present disclosure can significantly improve the mechanical reliability and electrical performance of multi-probe arrays at micro-scale, making it particularly suitable for high-frequency/high-speed testing scenarios. The more probe pairs for differential signals to which the above mechanism of the present disclosure is applied, the greater the improvement effect that can be achieved.

The above embodiments are only examples for illustrating the present disclosure, and are not intended to limit the scope of the present disclosure. Any other embodiments produced by modifying, changing, adjusting, or integrating the above-mentioned embodiments shall be substantially covered in the scope claimed in the present disclosure as long as they are not difficult for a person having ordinary skill in the art to contemplate. The scope of the present disclosure shall be determined by the claims as listed.

1. A probe for physically contacting an electronic device under test, comprising:
a probe tip configured to contact a corresponding pad of the electronic device under test during testing;
a probe tail disposed opposite to the probe tip; and
a probe body located between the probe tip and the probe tail and extending along a longitudinal axis, wherein:
the probe body comprises a first slit extending along the longitudinal axis such that the probe body has two probe arms separated by the first slit;
a transverse cross-section of the probe body perpendicular to the longitudinal axis has a width side and a thickness side, and the two probe arms are arranged along the width side; and
each of the two probe arms has a bump structure within the first slit, thereby forming two bump structures that face each other within the first slit.

2. The probe according to claim 1, wherein the two bump structures respectively have a contact surface, and when the probe body undergoes buckling during a testing process, the two bump structures contact each other through their respective contact surfaces and restricted relative sliding occurs between the contact surfaces.

3. The probe according to claim 2, wherein a length of each contact surface is not less than 10 micrometers.

4. The probe according to claim 1, wherein when the probe body does not undergo buckling, the two bump structures are separated from each other in a direction of the width side.

5. The probe according to claim 1, wherein a thickness of the probe body is greater than or equal to a width of the probe body.

6. The probe according to claim 1, wherein the width side is parallel to a bending direction of the two probe arms when the probe contacts the electronic device under test.

7. The probe according to claim 1, wherein positions of the two bump structures are level with a middle position of the first slit in a direction of the longitudinal axis.

8. The probe according to claim 1, wherein positions of the two bump structures are, in a direction of the longitudinal axis, closer to the probe tail than to the probe tip.

9. The probe according to claim 1, wherein when the two bump structures are viewed from a direction of the thickness side, the two bump structures are each a substantially trapezoidal.

10. The probe according to claim 1, wherein a transverse cross-section of each of the two probe arms taken perpendicular to the longitudinal axis is substantially rectangular or substantially trapezoidal.

11. The probe according to claim 1, wherein in the transverse cross-section of the probe body, the two probe arms are symmetrical with respect to the first slit as a center.

12. The probe according to claim 1, wherein shapes of transverse cross-sections respectively formed by the two probe arms are the same, but widths in a direction of the width side are different.

13. The probe according to claim 1, wherein a width of the bump structure of each of the two probe arms is not greater than a width of the same probe arm at the bump structure.

14. The probe according to claim 1, wherein each of the two probe arms is divided by the bump structure thereof into a first portion relatively near the probe tip and a second portion relatively near the probe tail, and a width of the first portion is greater than a width of the second portion.

15. The probe according to claim 1, wherein the first slit has a first end and a second end in a direction of the longitudinal axis, the first end being relatively near the probe tip and away from the probe tail, the second end being relatively near the probe tail and away from the probe tip, and a distance between the first end and the probe tip being greater than a distance between the second end and the probe tail.

16. The probe according to claim 15, wherein a second slit is formed between the first end and the probe tip.

17. The probe according to claim 16, wherein:
the second slit is connected and communicated with the first slit, and the two probe arms are separated by both the first slit and the second slit; and
each of the two probe arms has a first portion, a second portion, and a third portion, wherein:
the first portion and the second portion are located at the first slit and divided by the bump structure thereof into the first portion relatively near the probe tip and the second portion relatively near the probe tail;
the third portion is located at the second slit; and
a width of the third portion being greater than a width of the first portion, and the width of the first portion being greater than a width of the second portion.

18. A probe head for functionally testing an electronic device under test integrated in a semiconductor wafer, comprising:
a probe pair, each probe pair comprising two probes according to claim 1;
an upper guide plate unit comprising a first through-hole pair, the probe pair passing through the first through-hole pair; and
a lower guide plate unit comprising a second through-hole pair, the probe pair passing through the second through-hole pair;
wherein the two probes of the probe pair correspond to the same buckling direction, and the buckling direction is parallel to the width side.

19. The probe head according to claim 18, wherein two ends of each probe of the probe pair are offset from each other by a first distance by the upper guide plate unit and the lower guide plate unit, in a direction of the thickness side of the transverse cross-section of the probe body.

20. The probe head according to claim 19, wherein two ends of each probe of the probe pair are further offset from each other by a second distance by the upper guide plate unit and the lower guide plate unit, in a direction of the width side of the transverse cross-section of the probe body, and the second distance is greater than the first distance.

21. A probe card for functionally testing an electronic device under test integrated in a semiconductor wafer, comprising a circuit board; a space transformer disposed on the circuit board; and the probe head according to claim 18, disposed on a side of the space transformer opposite to the circuit board, wherein the probe tail of each probe of the probe head is configured to be electrically connected to the space transformer.

22. A probe system for functionally testing an electronic device under test integrated in a semiconductor wafer, comprising:
a fixture configured to support the semiconductor wafer;
a test equipment configured to be electrically connected to the electronic device under test to establish an electrical test procedure; and
the probe card according to claim 21, disposed on the test equipment.

23. An electronic device utilizing the probe card according to claim 21 to perform a high-frequency test procedure, wherein the high-frequency test procedure uses a high-frequency signal for testing and the high-frequency test procedure is a loopback test procedure.
